(19) United States
(12) Patent Application Publication
(10) Pub. No.: US 2009/0146187 A1
(43) Pub. Date: Jun. 11, 2009

(54) Nitride semiconductor element and process for producing the same

(75) Inventor: Yukio Shakuda, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/314,250

(22) Filed: Dec. 5, 2008

(30) Foreign Application Priority Data
Dec. 7, 2007 (JP) 2007-317195

(51) Int. Cl. H01L 29/205; H01L 21/20

(52) U.S. Cl. 257/201; 438/478; 257/E29.091; 257/E21.09

(57) ABSTRACT

An undoped GaN layer, a silicon film, an n type GaN layer, an MQW active layer and a p type GaN layer are stacked sequentially in this order on an AlN buffer layer formed on a sapphire substrate. In this manner, the silicon film is formed in the mid-section of the GaN layers. The AlN buffer layer is crystal-grown at a high temperature. The construction is formed such that a reflectivity of light from a crystal-growing surface is once decreased in a crystal-growing process of the n type GaN layer formed on the silicon film, and the reflectivity of light is increased from the crystal-growing surface in a crystal-growing process of a nitride semiconductor layer to be formed on the n type GaN layer.

### CROSS REFERENCE TO RELATED APPLICATIONS AND INCORPORATION BY REFERENCE

This application is based upon and claims the benefit of prior Japanese Patent Application P2007-317195 filed on Dec. 7, 2007; the entire contents of which are incorporated by reference herein.

### BACKGROUND OF THE INVENTION

1. Field of the Invention

The present invention relates to a nitride semiconductor element including an AlN buffer layer and a process for producing the nitride semiconductor element.

2. Description of the Related Art

A semiconductor element made of a gallium nitride-based compound semiconductor, i.e., a group III-V nitride semiconductor (hereinafter, referred to as nitride semiconductor), has been actively developed. The nitride semiconductor is used for: a blue LED serving as a light source for illumination, a backlight, and the like; an LED for multicoloration; an LD; and the like. It is difficult to produce the nitride semiconductor in a bulk single crystal form and therefore GaN is grown on a substrate made of different substances such as sapphire, SiC, or the like by utilizing a MOCVD (metal organic chemical vapor deposition) method. A sapphire substrate is excellent in the stability to epitaxial growth process in a high temperature ammonia atmosphere and accordingly particularly used as a substrate on which GaN is grown.

In producing a nitride semiconductor element, crystallinity of its nitride semiconductor layer is enhanced to manufacture a device with a high performance. Thus, for example, a low temperature GaN buffer layer or a low temperature AlN buffer layer is crystal-grown on a sapphire substrate at a low growth temperature of 400° C. to 600° C., and then a GaN semiconductor layer is grown.

When a low temperature AlN buffer layer is used, a low temperature AlN buffer layer having a thickness of 100 Å (angstrom) to 500 Å is formed on a substrate for growth at a low growth temperature of 400° C. to 600° C. This method has an advantage that the crystallinity and surface morphology of the resultant GaN semiconductor layer can be improved by growing GaN on such an AlN buffer layer.

However, the above method has strict limitation to the growth conditions of the buffer layer. Thereby, it is difficult to improve the semiconductor crystallinity and the surface morphology efficiently, and therefore the method is impractical.

To address this problem, Patent document 1 (Japanese Patent Application Publication No. 2002-154900) and Patent document 2 (Japanese Unexamined Patent Application Publication No. Hei 4-297023) propose that a low temperature GaN buffer layer is formed on a substrate for growth at a low growth temperature of 500° C. to 800° C. in place of the foregoing low temperature AlN buffer layer, and a nitride semiconductor crystal is grown on the low temperature GaN buffer layer.

The foregoing prior art can be expected to improve the crystallinity and the like of the nitride semiconductor crystal. However, the prior art has the following problems. Firstly, a growth temperature must be increased to 1000° C. or higher in the formation of a nitride semiconductor crystal after a low temperature GaN buffer layer is grown. During the process of increasing the growth temperature, the low temperature GaN buffer layer is deteriorated, and consequently does not serve as a buffer layer. Secondly, the increased growth temperature to such a high level causes a thermal strain in the GaN buffer layer already formed at a low temperature.

Furthermore, in either case of the low temperature GaN buffer layer or the low temperature AlN buffer layer, as the buffer layer with a smaller film thickness tends to have orderly oriented crystal axes in the GaN film that are grown on the buffer layer. This improves the crystallinity of the GaN film. However, the smaller film thickness likely causes a hexagonal facet to be formed on the surface of the GaN film, thereby deteriorating the surface morphology of the GaN film. Therefore, both buffer layers are questionable to be used in manufacturing a device.

To solve these problems, another method is proposed; specifically, a high temperature AlN buffer layer produced at a high temperature of 900° C. or higher is grown on a substrate for growth, and then a nitride semiconductor crystal is stacked on the high temperature AlN buffer layer. The growth conditions of the high temperature AlN buffer layer are, however, difficult to set in order to improve the crystallinity and surface morphology of the nitride semiconductor crystal formed on the AlN buffer layer. Moreover, it is difficult to produce a high quality nitride semiconductor crystal with high reproducibility because the production also depends on the growth conditions of the GaN film on the AlN buffer layer.

### SUMMARY OF THE INVENTION

The invention is made to solve the foregoing problems. An object of the present invention is to provide: a nitride semiconductor element allowing a high-quality nitride semiconductor crystal to be formed on a high temperature AlN buffer layer with high reproducibility; and a process for producing the nitride semiconductor element.

In order to achieve the above object, the nitride semiconductor element of the present invention includes at least: an AlN buffer layer disposed on a substrate for growth; and a GaN layer disposed on the AlN buffer layer, and also includes a silicon film formed in a mid-section of the GaN layer.

The nitride semiconductor element may include, in the foregoing construction, the silicon film formed at a height of not more than 100 nm above a boundary between the AlN buffer layer and the GaN layer.

The nitride semiconductor element may include, in the construction, the silicon film having a thickness of 0.05 nm or less.

The process for producing a nitride semiconductor element of the present invention includes: a first step of forming an AlN buffer layer on a substrate for growth; a second step of stacking a GaN layer on the AlN buffer layer; a third step of stacking a silicon film on the GaN layer; and a fourth step of stacking a GaN layer on the silicon film.

The process for producing a nitride semiconductor element may be a process as follows. Specifically, in the foregoing construction, the AlN buffer layer is formed at a growth temperature of 900° C. or higher. A reflectivity of light from a crystal-growing surface is once decreased in a crystal-growing process of the GaN layer in the fourth step, and then increased in a crystal-growing process of a nitride semiconductor layer formed on the GaN layer.

According to the present invention, the Si film is formed in a mid-section of the GaN layer formed on the AlN buffer layer. The crystallinity of the GaN layer on the Si film is accordingly improved. Moreover, the AlN buffer layer is formed at a growth temperature of 900° C. or higher. The reflectivity of light from the crystal-growing surface is once decreased in the crystal growth process of the GaN layer formed on the silicon film, and then increased in the crystal growth process of the nitride semiconductor layer formed on the GaN layer. Therefore, a nitride semiconductor element having high crystallinity and high surface flatness can be produced with high reproducibility.

### BRIEF DESCRIPTION OF DRAWINGS

FIG. 1 shows an example of a cross-sectional structure of a nitride semiconductor element of the present invention.

FIG. 2 shows an example of another cross-sectional structure of the nitride semiconductor element of the present invention.

FIG. 3 shows change in the crystallinity of a GaN film depending on the presence or absence of a Si film.

FIG. 4 is a schematic drawing of the variation of surface reflectivity measured while a semiconductor layer is crystal-grown.

FIG. 5 shows reflectivity variations in a GaN layer growth process when the Si film has a thickness of 0.24 Å.

FIG. 6 shows reflectivity variations in the GaN layer growth process when the Si film has a thickness of 0.9 Å.

FIG. 7 shows reflectivity variations in the GaN layer growth process without a Si film formed.

FIG. 8 shows reflectivity variations in the GaN layer growth process without a Si film formed when a low temperature GaN buffer layer is used.

FIG. 9 schematically shows the results of SIMS analysis performed in a direction from the surface side of the nitride semiconductor element to a sapphire substrate side.

### DETAILED DESCRIPTION OF THE INVENTION

An embodiment of the present invention will be described below with reference to the drawings. FIG. 1 shows an example of a cross-sectional structure of a nitride semiconductor element of the present invention.

An AlN buffer layer 2 is stacked on a sapphire substrate 1 serving as a substrate for growth, and a nitride semiconductor layer is crystal-grown on the sapphire substrate 1. The nitride semiconductor is formed by a known MOCVD method or the like. A nitride semiconductor refers to an AlGaInN quaternary mixed crystal, a so-called group III-V nitride semiconductor, and can be represented by AlₓGa_{y}In_{z}N (x+y+z=1, 0≦x≦1, 0y≦1, 0≦z≦1).

On the AlN buffer layer 2 formed on the sapphire substrate 1, an undoped GaN layer 3, a silicon (Si) film 31, an n type GaN layer 4 doped with Si, an MQW active layer 5, and a p type GaN layer 6 doped with Mg are stacked in this order. In this example, the undoped GaN layer 3 and the n type GaN layer 4 correspond to a GaN layer described in claims. These semiconductor layers are formed by the MOCVD method. The MQW active layer 5 has a multiple quantum well structure formed of a barrier layer made of GaN and a well layer made of Inₓ₁Ga₁₋ₓ₁N (0≦X≦1).

In the present invention, the AlN buffer layer 2 is crystal-grown at a high temperature of 900° C. or higher, and the Si film 31 is formed in the mid-section of the GaN layer, i.e. between the undoped GaN layer 3 and the n type GaN layer 4. Thereby, the crystal quality of the n type GaN layer 4 formed after the Si film 31 can be enhanced. The improved crystal quality of the n type GaN layer 4 leads to the improvement of the crystal quality of the MQW active layer 5 and the p type GaN layer 6 formed on the n type GaN layer 4 in this sequence.

In the description about the production process below, as the undoped GaN layer 3 has a thickness of, for example, approximately 1000 Å (100 nm), the silicon film 31 is preferably formed at a position of 100 nm or less from the boundary between the AlN buffer layer 2 and the undoped GaN layer 3. This is because the crystallinity of the GaN layer is seriously deteriorated if a thickness range of the GaN layer formed on the AlN buffer layer is within 100 nm or less and because, if the silicon film is formed at the position, the crystallinity of the GaN layer and the nitride semiconductor layer formed on the silicon film is drastically improved, and a larger effect is expected.

Next, a process for producing the nitride semiconductor element in FIG. 1 will be described. A sapphire substrate 1 serving as a substrate for growth is firstly put in a MOCVD (metal organic chemical vapor deposition) system, and heated to approximately 1050° C. while a hydrogen gas is being introduced therein to thermally clean the sapphire substrate 1. The temperature is maintained or decreased to a suitable temperature of 900° C. or higher (for example, to a growth temperature of 910° C.), and thus a high temperature AlN buffer layer 2 is grown to have a thickness of 20 Å (2 nm). A reaction gas (for example, TMA) used as an Al raw material and a reaction gas (for example, NH₃) used as an N raw material are supplied to form the high temperature AlN buffer layer 2.

After the high temperature AlN buffer layer 2 is formed, supplying TMA is stopped. While ammonia is being supplied, the growth temperature is set at approximately 905° C., and the pressure is set at 150 Torr or more (for example, 200 Torr). For example, trimethylgallium (TMGa) is then supplied at a rate of 20 μmol/minute to grow an undoped GaN layer 3 having a film thickness of approximately 1000 Å. A reason why the growth pressure of the GaN layer crystal-grown on the high temperature AlN buffer layer 2 is set at 150 Torr or more is that the crystal is three-dimensionally grown to increase the size of the growth nucleus. Meanwhile, a reason why the growth temperature is set at 900° C. or higher is that excessively low growth temperature causes the crystallinity of GaN to be deteriorated.

As described above, in a case where the undoped GaN layer 3 is to be grown after the AlN buffer layer 2 is grown, if the growth temperature of the AlN buffer layer 2 and the crystal growth temperature of the undoped GaN layer 3 are approximately 910° C. and approximately 905° C., respectively, the growth of the undoped GaN layer 3 can immediately be started with little change in the growth temperature. Consequently, the deterioration of the AlN buffer layer 2 due to heating can be prevented. Furthermore, a thermal strain of the AlN buffer layer 2 due to the difference in growth temperature can be prevented from occurring.

The supply of TMGa is then stopped. Only silane (SiH₄) and ammonia (NH₃) are supplied as a raw material gas. A Si film 31 is thereby crystal-grown to have a thickness of 0.24 Å (24 pm) while the temperature is maintained at 905° C. The growth temperature is then increased to approximately 1020° C. Thereafter, for example, trimethylgallium (TMGa) is supplied at a rate of 20 μmol/minute, and silane (SiH₄) is supplied as an n type dopant gas to form an n type GaN layer 4 having a thickness of approximately 2.5 μm.

The supplying TMGa and silane is then stopped. Thereafter, the substrate temperature is decreased between 700° C. and 800° C. in a mixed atmosphere of ammonia and hydrogen. Trimethylindium (TMIn) and trimethylgallium (TMGa) are supplied at 200 μmol/minute and at 20 μmol/minute, respectively to stack an InGaN well layer of an MQW active layer 5. Then, the supply of only TMIn is stopped to stack a barrier layer made of undoped GaN. A multiple quantum well structure is thus formed by repeatingly stacking a GaN barrier layer and an InGaN well layer.

The growth temperature is increased to approximately 1020° C. after the MQW active layer 5 is grown. Thereafter, trimethylgallium (TMGa) used as the raw gas of Ga atoms, ammonia (NH₃) used as the raw gas of nitrogen atoms and CP₂Mg (bis-cyclopentadienyl magnesium) used as a dopant material of p type impurity Mg are supplied to grow a p type GaN layer 6. The MQW active layer 5 has a thickness of approximately 0.1 μm. The p type GaN layer 6 has a thickness of approximately 0.2 μm.

The formation of respective semiconductor layers is performed as follows. That is, with hydrogen or nitrogen serving as a carrier gas, supplied are necessary gases including reaction gases corresponding to the components of the respective semiconductor layers such as triethylgallium (TEGa), trimethylgallium (TMG), ammonia (NH₃), trimethylaluminium (TMA) and trimethylindium (TMIn), silane (SiH₄) serving as a dopant gas used to make an n type and CP₂Mg (cyclopentadienyl magnesium) serving as a dopant gas used to make a p type. Then, the semiconductor layers are grown sequentially within a growth temperature range of approximately 700° C. to 1200° C. The semiconductor layers can thereby be formed in desired compositions, in desired conductivity types and in necessary thicknesses.

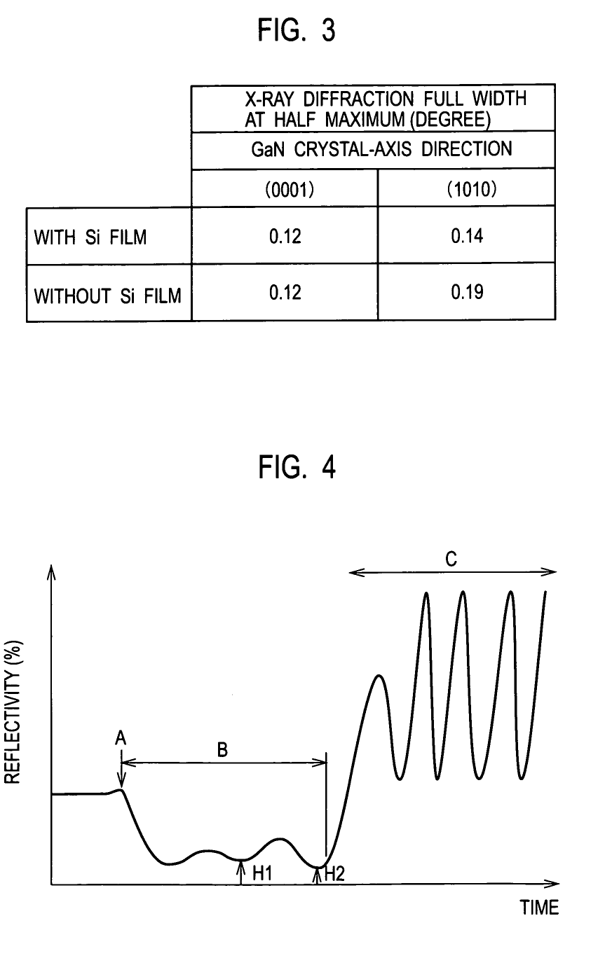

FIG. 3 show the results of examinations on the nitride semiconductor element thus formed how the crystallinity of the n type GaN layer 4 on the Si film 31 changes depending on, for example, the presence and absence of the Si film 31 in FIG. 1. One of examinations was performed as follows. Specifically, an AlN buffer layer 2, an undoped GaN layer 3 and a Si film 31 were sequentially stacked on a sapphire substrate 1, and then an n type GaN layer 4 was crystal-grown thereon as in the present invention. The surface of the n type GaN layer 4 was scanned with an X-ray diffractometer to analyze a spectrum. On the other hand, in a comparative examination, an AlN buffer layer 2 and an undoped GaN layer 3 were sequentially stacked on a sapphire substrate 1, and then an n type GaN layer 4 was directly crystal-growing on the undoped GaN layer 3 without a Si film 31 being formed. The surface of the n type GaN layer 4 was scanned with an X-ray diffractometer to analyze a spectrum. The full width at half maximum of each spectrum was measured to determine the crystallinity.

The growth directions of the undoped GaN layer 3 and the n type GaN layer 4 were changed from each other to measure an X-ray diffraction full width at half maximum; i.e., in two directions. (0001) represents a c-axis direction. (10-10) represents an m-axis direction. These growth directions becomes available by setting the growth main surface of the sapphire substrate 1, which is a substrate for growth, as a C plane {0001} and an M plane {10-10}.

When the C plane being a polar plane is used as the growth main surface, there is no difference in the X-ray diffraction full width at half maximum value between the presence and absence of the Si film 31. On the other hand, when the M plane being a non-polar plane is used as the growth main surface, the X-ray diffraction full width at half maximum value of 0.14 degree is obtained with the Si film 31, whereas that of 0.19 degree is obtained without the Si film 31. When the Si film 31 is formed, the crystal axis directions in the n type GaN layer 4 are uniform, suggesting a value of high crystallinity. It is understood that the Si film thus formed in the mid-section of the GaN layer increases the crystallinity of the GaN layers on the Si film.

Now, a crystal quality to be considered includes surface morphology and surface flatness in addition to the crystallinity. When the Si film is simply formed in the mid-section of the GaN layer, the surface flatness of the GaN layer is not necessarily enhanced. A method for forming a GaN layer having a high crystal quality and high reproducibility will be described below.

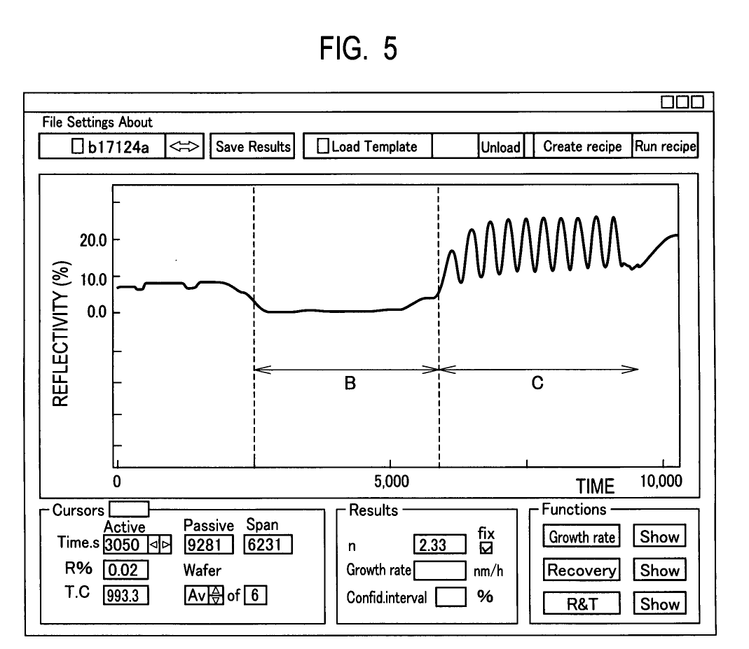

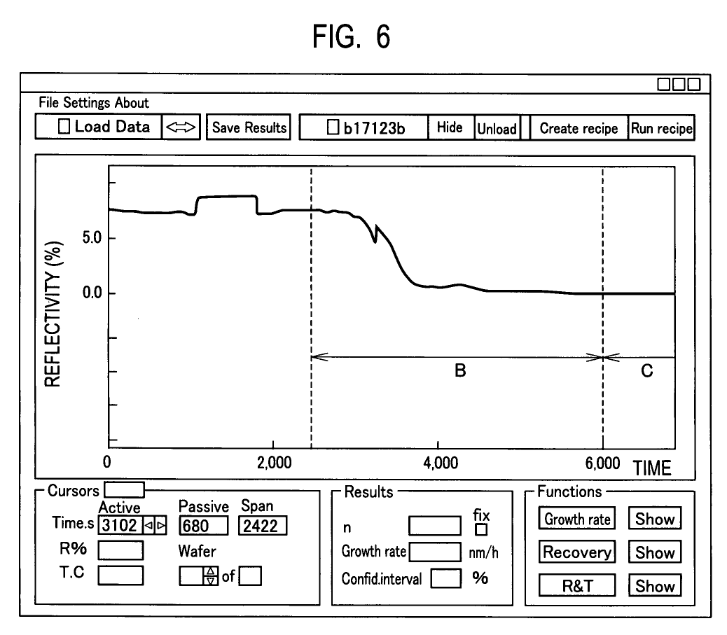

Infrared ray is irradiated on the surface of the semiconductor layer grown in the crystal-growing process of the AlN buffer layer 2, the undoped GaN layer 3, the Si film 31 and the n type GaN layer 4 as shown in FIG. 1. The reflectivity of the semiconductor layer surface is measured. FIG. 5 and FIG. 6 show a relationship between the reflectivity (longitudinal axis) and time (second) (transverse axis). To be specific, a window allowing light to transmit therethrough is provided in the upper portion of the growth chamber of MOCVD system. An infrared-ray LED and an infrared-ray detector are disposed close to the window to measure infrared ray. When the infrared-ray LED is lit in the above construction, the infrared ray passes through the window and falls on a wafer being crystal-grown in the growth chamber. Then, the infrared ray is reflected. The reflected infrared ray is detected by the infrared-ray detector disposed close to the window. Reflectivity is then calculated from a ratio of the amount of the infrared ray detected by the infrared-ray detector to the amount of the light emission of the infrared-ray LED.

FIG. 4 illustrates these infrared ray reflectivities. At a time point A shown in FIG. 4, the GaN layer after the Si film 31 is formed begins crystal-growing. In the example in FIG. 1, the n type GaN layer 4 begins crystal-growing at the time point A. The reflectivity is approximately 8% to 10% before the n type GaN layer 4 begins crystal-growing. Then, the n type GaN layer 4 begins crystal-growing from the time point A. A time period B indicates a time period during which the n type GaN layer 4 crystal-grows. The reflectivity value fluctuates at a cycle of ½ of a wavelength λ of the infrared ray used to monitor the reflectivity as shown in a time period C when the n type GaN layer 4 crystal-grows to be thicker and when the MQW active layer 5 and the p type GaN layer 6, which are formed on the n type GaN layer 4, crystal-grow. This is because the infrared ray is reflected at an interface between layers having a different electron density (refractive index) and the reflected lights interfere with each other in a thin film on the substrate, resulting in the fluctuation pattern on a reflectivity curve at a cycle of λ/2.

The cycles of the fluctuation pattern in the time period C following the time period B include information on a film thickness. The fluctuation width includes information on roughness of the surface and the interface. A rougher surface drastically reduces the reflectivity. It is known that, in order to enhance the surface flatness of the GaN layer (n type GaN layer 4 in FIG. 1) formed on the Si film, i.e., for example, to make the surface formed close to a mirror surface, the reflectivity in the time period B needs to be once reduced and thereafter needs to be increased in a stage of crystal-growing a nitride semiconductor layer (MQW active layer 5 in FIG. 1) formed on the GaN layer. The curve in the time period B needs to be shaped like the bottom of a pot. The narrower minimum range of the reflectivity fluctuation of the light in the time period B, the more preferable. For example, minimal values H1 and H2 of the reflectivity variations in the time period B are then checked to determine the relationship between the surface state and the thickness of the Si film 31.

FIG. 5 shows a case where the thickness of the Si film 31 is 0.24 Å. The minimum value of the reflectivity in the time period B is 0.02% in this case. The shape of the curve in the time period B forms the shape of the bottom of a pan, indicating that the reflectivity is reduced from a time point at which the n type GaN layer 4 begins crystal-growing, and that the reflectivity is then increased until the time period C.

On the other hand, FIG. 6 shows a case where the thickness of the Si film 31 is 0.9 Å. The shape of the curve in the time period B does not form the shape of the bottom of a pan. This indicates that the reflectivity is reduced from a time point at which the n type GaN layer 4 begins crystal-growing and converges to zero in the time period B, but thereafter is by no means increased. A periodic fluctuation pattern as seen in the time period C in FIG. 5 does not appear. This indicates that light is reflected irregularly on the surface of the MQW active layer 5 and the p type GaN layer 6 on which crystals grow. It can be seen from this that the surface flatness of the growing n type GaN layer 4 is extremely low. It is considered from these that the Si film 31 desirably has a thickness of approximately 0.5 Å (0.05 nm) or less.

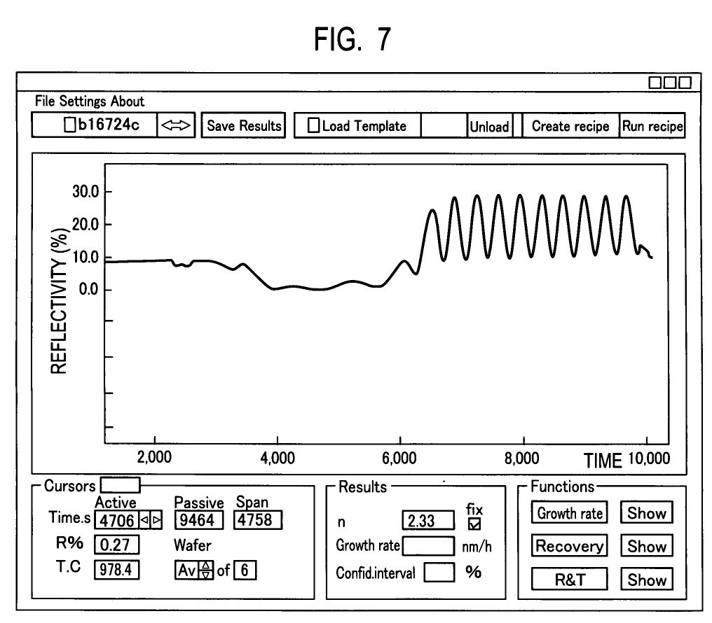

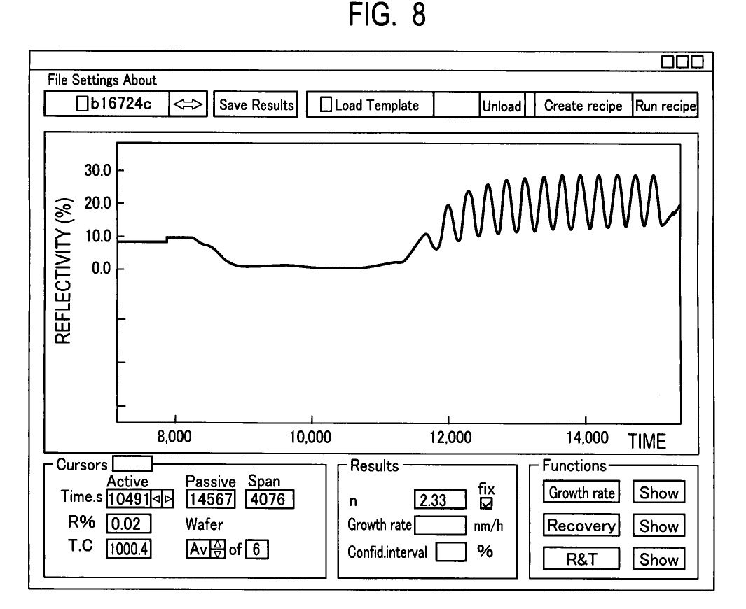

FIG. 7 and FIG. 8 show graphs comparatively showing measurement results of the infrared ray reflectivity of growing surfaces. FIG. 7 shows an infrared ray reflectivity obtained in a construction in which the n type GaN layer 4 is directly crystal-grown on the undoped GaN layer 3 in FIG. 1 without the Si film 31 being formed, and corresponds to FIG. 3 in which no Si film is formed. In FIG. 7, reflectivity fluctuation appears in a time period corresponding to the time period B (not shown), and the maximum and minimum values thereof are formed. The minimum value is 0.27%. The maximum value is 0.62%. Consequently, the minimum value is larger than that in FIG. 5.

On the other hand, FIG. 8 shows an infrared ray reflectivity obtained in a construction in which the AlN buffer layer 2 in FIG. 1 is replaced with a GaN buffer layer and no Si film 31 is formed. The minimum value of the reflectivity is approximately 0.02% in a time period corresponding to the time period B (not shown). This is the same minimum reflectivity value as that in FIG. 5.

As has been described, it is understood that the flatness and crystallinity of the GaN layer on the Si film can be enhanced with high reproducibility if the nitride semiconductor element with a high temperature AlN buffer layer and a silicon (Si) film inserted in a mid-section of a GaN layer is constructed such that the light reflectivity of the crystal-growing surface is once reduced in a crystal-growing process of a GaN layer formed on the Si film, and such that the light reflectivity of the crystal-growing surface is increased in a crystal-growing process of a nitride semiconductor layer formed on the GaN layer. Thus, a nitride semiconductor element having a high crystal quality is produced.

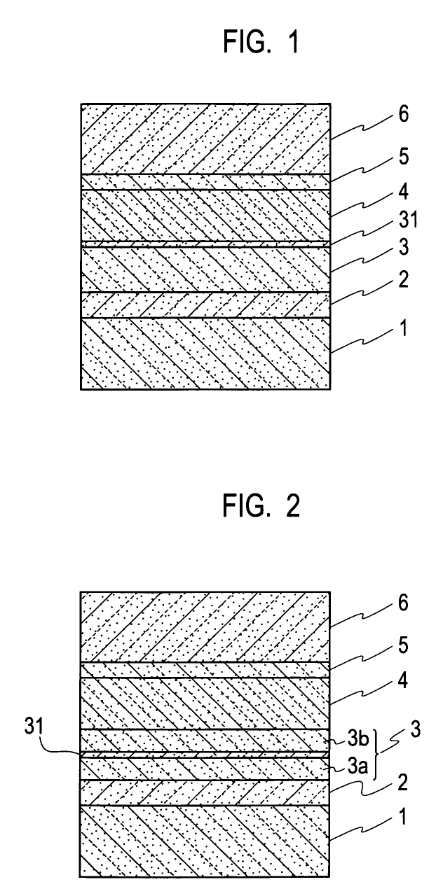

FIG. 2 shows almost the same layered structure as in FIG. 1 but the difference from FIG. 1 is a position where the Si film 31 is inserted. In FIG. 1, the undoped GaN layer 3 and the n type GaN layer 4 are present as a GaN layer, and the Si film 31 is inserted between the undoped GaN layer 3 and the n type GaN layer 4. On the other hand, in FIG. 2, an undoped GaN layer 3 and an n type GaN layer 4 are present as a GaN layer, but a Si film 31 is inserted in a mid-section of the undoped GaN layer 3. Two undoped GaN layers 3 are designated as undoped GaN layers 3a and 3b. The undoped GaN layer 3b is crystal-grown on the Si film 31 formed on the undoped GaN layer 3a. The flatness and crystallinity of the undoped GaN layer 3b are enhanced in the same manner described in FIG. 1, and the crystal quality of the nitride semiconductor element is improved.

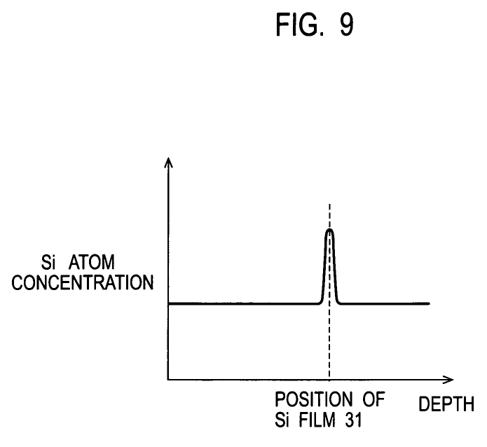

FIG. 9 is a graph schematically showing the result of an SIMS (Secondary Ion Mass Spectrometry) analysis performed from the nitride semiconductor element surface (p type GaN layer 6) side to the sapphire substrate 1 side in the construction in FIG. 2, for example. The transverse axis represents the depth from the surface of the p type GaN layer 6. The longitudinal axis represents the concentration of silicon atoms. Even when the resolution in the SIMS analysis is, for example, at most approximately 100 Å, the Si concentration is markedly increased at a position where the silicon film 31 has a thickness of 0.05 nm.

As has been described so far, the present invention, being taken for granted, includes various embodiments and the like which are herein not described. Therefore, the technological scope of the present invention is intended to be defined only by the following claims pertinent to the viewpoints of the above descriptions.

1. A nitride semiconductor element comprising at least:
an AlN buffer layer disposed on a substrate for growth; and
a GaN layer disposed on the AlN buffer layer, wherein
a silicon film is formed in a mid-section of the GaN layer.

2. The nitride semiconductor element of claim 1, wherein:
the silicon film is formed at a height of not more than 100 nm above a boundary between the AlN buffer layer and the GaN layer.

3. The nitride semiconductor element of claim 1, wherein:
the silicon film has a thickness of 0.05 nm or less.

4. A process for producing nitride semiconductor element comprising:
a first step of forming an AlN buffer layer on a substrate for growth;
a second step of stacking a GaN layer on the AlN buffer layer;
a third step of stacking a silicon film on the GaN layer; and
a fourth step of stacking a GaN layer on the silicon film.

5. The process for producing nitride semiconductor element of claim 4, wherein:
the AlN buffer layer is formed at a growth temperature of 900° C. or higher; and
a reflectivity of light from a crystal growing surface is once decreased in a crystal-growing process of the GaN layer in the fourth step; and
the reflectivity of light from the crystal-growing surface is increased in a crystal-growing process of a nitride semiconductor layer to be formed on the GaN layer.

6. The nitride semiconductor element of claim 2, wherein:
the silicon film has a thickness of 0.05 nm or less.
